(19) United States
(12) Patent Application Publication
(10) Pub. No.: US 2012/0149135 A1
(43) Pub. Date: Jun. 14, 2012

(54) SEMICONDUCTOR DEVICE MANUFACTURING METHOD THAT ALLOWS REWORK RATE IN MANUFACTURING STEP TO DECREASE

(75) Inventors: Takashi SUGIMURA, Chuo-ku (JP); Shinji YANAGI, Chuo-ku (JP)

(73) Assignee: ELPIDA MEMORY, INC., Tokyo (JP)

(21) Appl. No.: 13/311,193

(22) Filed: Dec. 5, 2011

(30) Foreign Application Priority Data
Dec. 14, 2010 (JP) 2010-278137

(51) Int. Cl. H01L 21/66

(52) U.S. Cl. 438/14; 257/E21.53

(57) ABSTRACT

A semiconductor device manufacturing method includes: forming a first pattern in a first film to be processed on a semiconductor substrate; measuring a first distance, which is a dimension in a predetermined direction in the first pattern; forming a second film to be processed on the first pattern; forming a second pattern in a photoresist formed on the second film to be processed; and measuring a second distance, which is a dimension in a predetermined direction in the second pattern. Whether or not the second pattern is defective is determined based on either the first distance or a value calculated from the first and second distances.

This application is based upon and claims the benefit of priority from Japanese Patent Application No. 2010-278137 filed on Dec. 14, 2010, the content of which is incorporated by reference.

### BACKGROUND OF THE INVENTION

1. Field of the Invention

The present invention relates to a method for manufacturing a semiconductor device.

2. Description of Related Art

To manufacture a semiconductor device, a photoresist is applied over a film to be processed, such as an insulating film and a metal film, on a semiconductor substrate, and the film to be processed is patterned by using a resist mask formed in a photolithography process.

When a semiconductor device is manufactured as described above, an operator checks whether or not the dimension of the processed pattern is within an acceptable value of a process design (hereinafter referred to as acceptable design value) determined for each product specification. When a wafer has a processed pattern whose dimension does not fall within the acceptable design value, the wafer is handled as a defective product and is rejected before it reaches the manufacturing stage. Rejecting a defective product before it reaches the manufacturing stage prevents the defective product from being delivered to a customer, but the manufacturing yield decreases and the cost increases. It is therefore necessary to minimize the rate of occurrence of defective products (defect rate).

On the other hand, some manufacturing steps allow a temporarily rejected defective product to be reworked into a non-defective product and returned to the manufacturing process. A representative example of such steps is a photolithography step for forming a resist mask. A wafer, in which the position and dimension of the pattern in a resist mask have been measured and whose measured values are judged as not falling within acceptable design values, is temporarily rejected as a defective product but the manufacturing process can be resumed after only the resist mask is removed, together with wafers having been judged to fall within acceptable values. Defective products can be reworked into non-defective products this way, whereby the defect rate can be lowered. Nevertheless, the rate of occurrence of reworking (rework rate) is desirably lowered because reworking results in another increase in cost.

JP 2003-224061A discloses an example of a method for measuring overlay misalignment between a pattern formed in a pre-processing step and a pattern formed in a post-processing step that follows the pre-processing step. Hereinafter, JP 2003-224061A will be referred to as Patent Document 1.

It is extremely difficult to ensure the alignment margin for semiconductor devices that have already been miniaturized and thus the defect and rework rates have been increasing. A description will now be made of an acceptable design value of alignment with reference to the step of forming a cylinder hole in a DRAM (dynamic random access memory).

To form a cylinder hole, a resist mask for the cylinder hole is first aligned with a contact pad connected to a wiring layer and formed on an insulating film that covers the contact pad. The contact pad is provided between the wiring layer formed in a lower portion and the cylinder to be formed in an upper portion and serves to increase the margin of alignment between the wiring layer and the cylinder. The insulating film is then so etched by using the resist mask as an etching mask in which the cylinder hole is formed in the insulating film with part of the upper surface of the contact pad exposed at the bottom of the cylinder hole. At this point, since the bottom of the cylinder hole needs to be positioned above the contact pad, the margin of alignment between the contact pad and the resist mask is set to a variety of values in accordance with process variations, which change the areas of the contact pad and the resist mask. That is, the margin of alignment between the two patterns increases as the area of the pattern for the contact pad in the plan view increases and as the area of the bottom of the cylinder hole decreases.

On the other hand, an acceptable design value in a manufacturing step is determined taking into consideration the worst case. An acceptable design value used to control the manufacturing step is therefore set based on the narrowest margin of alignment between a contact pad having the smallest pattern area in the plan view and a cylinder hole having the largest bottom area. In the actual manufacturing step, however, the worst case seldom occurs, and a wafer has a room large enough to increase the acceptable design value in most cases. Despite the fact described above, whether a processed wafer is defective or not is judged based on the narrowest alignment margin. Controlling a manufacturing step using the narrowest alignment margin disadvantageously results in an increase in the rework rate.

### SUMMARY

In one embodiment, there is provided a semiconductor device manufacturing method that includes: forming a first film to be processed on a semiconductor substrate; forming a first pattern in the first film to be processed; measuring a first distance, which is a dimension in a predetermined direction in the first pattern; forming a second film to be processed on the first pattern; forming a second pattern in a photoresist formed on the second film to be processed; and measuring a second distance, which is a dimension in a predetermined direction in the second pattern. Whether or not the second pattern is defective is determined based on either the first distance or a value calculated from the first and second distances.

### BRIEF DESCRIPTION OF THE DRAWINGS

The above features and advantages of the present invention will be more apparent from the following description of certain preferred embodiments taken in conjunction with the accompanying drawings, in which:

FIGS. 1A and 1B are cross-sectional views showing an example of the configuration of a DRAM according to an exemplary embodiment;

FIGS. 2A to 2C are plan views for describing a semiconductor device manufacturing method according to an exemplary embodiment;

FIGS. 3A to 3C are cross-sectional views for describing the semiconductor device manufacturing method according to the exemplary embodiment;

FIGS. 4A to 4C are plan views for describing the semiconductor device manufacturing method according to the exemplary embodiment;

FIGS. 5A to 5C are cross-sectional views for describing the semiconductor device manufacturing method according to the exemplary embodiment;

FIGS. 6A to 6C are plan views for describing the semiconductor device manufacturing method according to the exemplary embodiment;

FIGS. 7A to 7C are cross-sectional views for describing the semiconductor device manufacturing method according to the exemplary embodiment;

FIGS. 8A to 8C are plan views for describing the semiconductor device manufacturing method according to the exemplary embodiment;

FIGS. 9A to 9C are cross-sectional views for describing the semiconductor device manufacturing method according to the exemplary embodiment;

FIGS. 10A to 10C are plan views for describing the semiconductor device manufacturing method according to the exemplary embodiment;

FIGS. 11A to 11C are cross-sectional views for describing the semiconductor device manufacturing method according to the exemplary embodiment;

FIG. 12 is a manufacturing flowchart showing two steps with reference to which the semiconductor device manufacturing method according to the exemplary embodiment is described in detail;

FIG. 13 shows an exemplary image obtained by capturing an alignment mark section with a camera at the time of measurement in step (12) shown in FIG. 12;

FIG. 14 is a plan view showing an example of the layout of semiconductor devices and alignment marks on a wafer;

FIG. 15A is a cross-sectional view showing part of the semiconductor device after hole pattern 20D is formed;

FIG. 15B is a cross-sectional view showing part of the semiconductor device after cylinder hole 27A is formed;

FIG. 16 is a table summarizing possible tolerances of an acceptable overlay value within the acceptable design value range of the dimension of a contact pad and the dimension of the bottom of a cylinder hole;

FIG. 17 is a table summarizing possible acceptable values of the dimension of the bottom of the cylinder hole for the tolerances of the acceptable overlay value within the acceptable design value range of the dimension of the contact pad;

FIG. 18 is a block diagram showing an example of the configuration of a measuring apparatus used in the exemplary embodiment;

FIG. 19A shows an image representing a state in which cylinder holes are formed in ideal positions above contact pads;

FIG. 19B shows an image representing a state in which cylinder holes are not ideally overlaid above contact pads but are shifted therefrom by a value greater than an acceptable design value;

FIG. 19C shows an image representing a state in which formed cylinder holes have a larger size than an acceptable design value; and

FIG. 20 is a table showing an example of a case where a plurality of types of registered image are provided.

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

A description will be made of the configuration of a semiconductor device according to an exemplary embodiment. In the exemplary embodiment, the semiconductor device is assumed to be a DRAM.

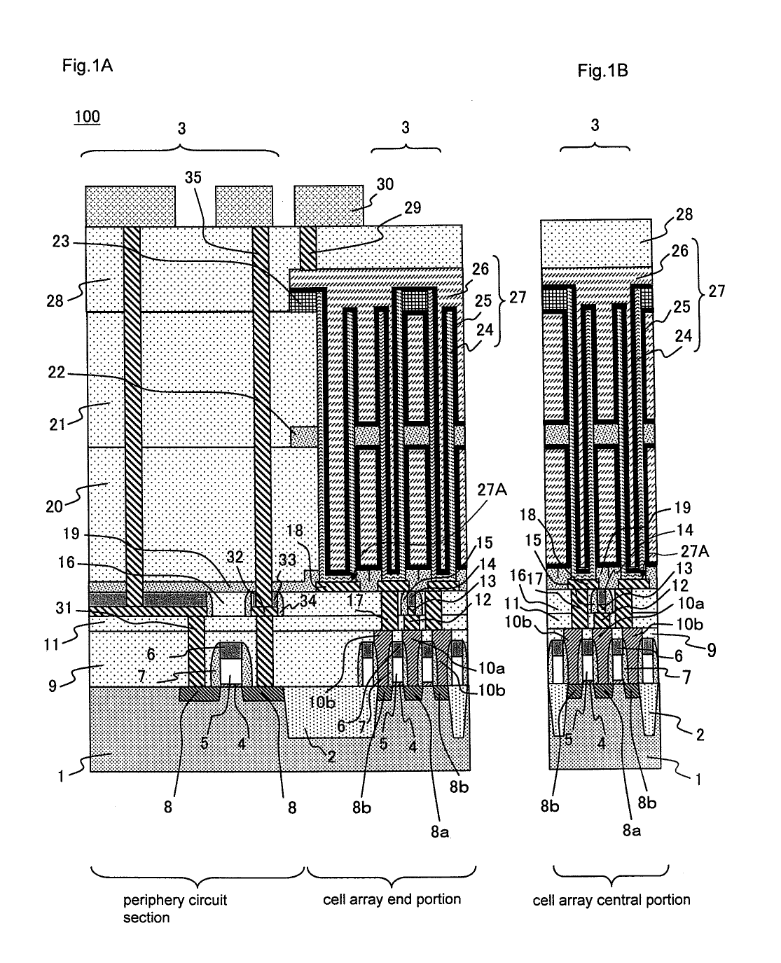

FIGS. 1A and 1B are cross-sectional views showing an example of the configuration of a DRAM according to the exemplary embodiment. In the exemplary embodiment, a circuit formation region of the DRAM is broadly divided into a cell array section where memory cells are provided and a periphery circuit section is provided around the cell array section for ease of description.

FIG. 1A shows the periphery circuit section and a cell array end portion, and FIG. 1B shows a cell array central portion. The cell array end portion and the cell array central portion are collectively called the cell array section in some cases. In the DRAM according to the exemplary embodiment, a semiconductor substrate that forms a base is assumed to be a silicon substrate. It is further noted that not only a semiconductor substrate alone but also a semiconductor substrate on which a semiconductor device is being manufactured and a semiconductor substrate on which a semiconductor device has been formed are collectively called a wafer.

The configuration common to the cell array section and the periphery circuit section in DRAM 100 according to the exemplary embodiment will first be described with reference to FIGS. 1A and 1B.

In each of the cell array section and the periphery circuit section, planar MOS (metal oxide semiconductor) transistors (hereinafter referred to as MOS transistors) are provided on silicon substrate 1. The MOS transistors are positioned in active regions 3, each of which is surrounded by STI (shallow trench isolation) 2, which forms a device isolation region, provided in silicon substrate 1. Each of the MOS transistors includes gate insulating film 4 provided on the surface of silicon substrate 1, gate electrode 5 provided on gate insulating film 4, and diffusion layer 8, which forms a source region and a drain region, provided in a portion under gate insulating film 4 but therearound. Two MOS transistors are shown in active region 3 shown in FIG. 1B for ease of description, but several thousand to several hundred thousand MOS transistors are actually disposed in the cell array section.

Gate electrode 5 includes an upper surface covered with an insulating film 6 and a side surface covered with sidewall insulating film 7, as shown in FIGS. 1A and 1B. Diffusion layer 8 is provided in a peripheral domain of a portion under gate insulating film 4, but not in the portion immediately below gate insulating film 4 covered with gate electrode 5. Diffusion layer 8 is actually provided in the vicinity of the surface of the portion of silicon substrate 1 that is covered with first interlayer insulating film 9. Diffusion layer 8 is formed by diffusing conductive impurity whose conductivity type is opposite the conductivity type of much conductive impurity contained in silicon substrate 1. In the following description where two diffusion layers 8 in a single MOS transistor should be distinguished from each other, one diffusion layer is called diffusion layer 8a and the other is called diffusion layer 8b, as shown in FIGS. 1A and 1B.

The configuration of the cell array section will next be described with reference to the cross-sectional view of FIG. 1A showing the cell array end portion and the cross-sectional view of FIG. 1B. The cell array section includes memory cells each of which includes the MOS transistor described above and capacitor 27. Capacitor 27 is a cylinder-type capacitor.

Capacitor 27 includes lower electrode 24, capacitor film 25, and upper electrode 26. Diffusion layer 8a, which is shared by the two MOS transistors, is connected to first wiring line 13, which forms a bit line, via first contact plug 10a and second contact plug 12. Diffusion layer 8b of each of the MOS transistors is connected to lower electrode 24 of capacitor 27 via first contact plug 10b, third contact plug 17, and contact pad 18.

Each of first contact plugs 10a and 10b passes through first interlayer insulating film 9 and is positioned between sidewall insulating films 7 of adjacent MOS transistors. First contact plug 10a is connected to second contact plug 12, which passes through second interlayer insulating film 11. First contact plug 10b is connected to third contact plug 17, which passes through second interlayer insulating film 11 and third interlayer insulating film 16.

First wiring line 13 is provided over second interlayer insulating film 11 and connected to second contact plug 12. First wiring line 13 includes an upper surface covered with insulating film 14 and a side surface covered with sidewall insulating film 15.

Contact pad 18 is provided on third interlayer insulating film 16 and connected to third contact plug 17, which passes through third interlayer insulating film 16. Contact pad 18 is provided to ensure a margin of alignment between capacitor 27 and third contact plug 17.

Cover film 19, which protects third interlayer insulating film 16, fourth interlayer insulating film 20, and fifth interlayer insulating film 21 are provided in this order over contact pad 18. Lower electrode 24, which has a cylinder shape, is provided in cylinder hole 27A, which passes through cover film 19, fourth interlayer insulating film 20, and fifth interlayer insulating film 21 and reaches the upper surface of contact pad 18. Contact pad 18 is thus connected to lower electrode 24. The exposed surface of lower electrode 24 is covered with capacitor film 25, which is covered with upper electrode 26. Upper electrode 26 is covered with sixth interlayer insulating film 28.

To prevent capacitors 27 from collapsing, first beam 22 and second beam 23 are provided between the side surfaces of adjacent capacitors 27. First beams 22 are provided in the vicinity of the center of capacitors 27, and second beams 23 are provided in the vicinity of upper portions of the capacitors. This configuration allows adjacent capacitors 27 to support each other via the beams and prevents capacitors 27 from collapsing even when a horizontal force acts on the capacitors in the manufacturing process.

Fourth contact plug 29 passing through sixth interlayer insulating film 28 is provided in the cell array end portion and connected to second wiring line 30 provided over sixth interlayer insulating film 28. Upper electrodes 26 of capacitors 27 are connected to second wiring line 30 via fourth contact plug 29.

The configuration of the periphery circuit section will next be described with reference to the cross-sectional view of the periphery circuit section shown in FIG. 1A.

Diffusion layer 8 in the MOS transistor in the periphery circuit section is connected to third wiring line 32 via fifth contact plug 31. Third wiring line 32 is connected to second wiring line 30 via sixth contact plug 35. Fifth contact plug 31 is so provided that it passes through first interlayer insulating film 9 and second interlayer insulating film 11. Third wiring line 32 is provided over second interlayer insulating film 11 and covered with insulating film 33 and sidewall insulating film 34. Cover film 19, fourth interlayer insulating film 20, fifth interlayer insulating film 21, and sixth interlayer insulating film 28 are provided in this order over insulating film 33. Sixth contact plug 35 passes through insulating film 33, cover film 19, fourth interlayer insulating film 20, fifth interlayer insulating film 21, and sixth interlayer insulating film 28 and connects second wiring line 30 to third wiring line 32.

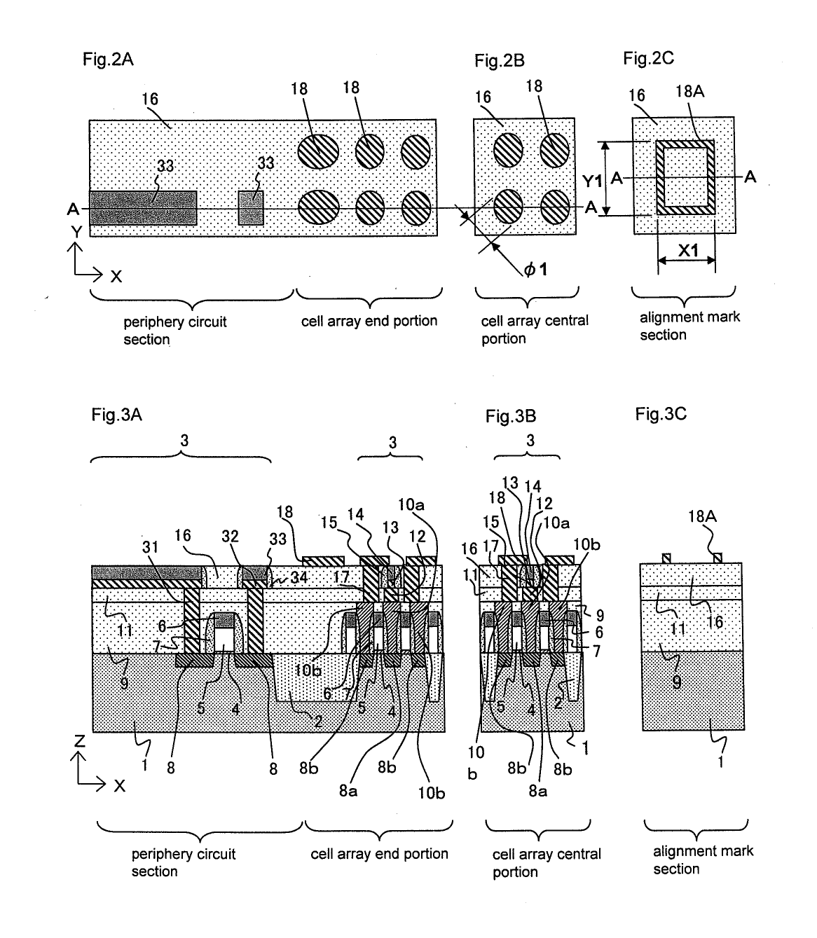

A semiconductor device manufacturing method according to an exemplary embodiment will next be described with reference to the thus configured DRAM shown in FIGS. 2A, 2B, and 2C to 11A, 11B, and 11C.

A semiconductor device manufacturing method according to the exemplary embodiment is intended to be used in a photolithography step and is particularly effective in a photolithography step in which alignment with a pattern formed in an underlying portion is necessary. As an example, the semiconductor device manufacturing method according to the exemplary embodiment is used to form cylinder hole 27A, which forms a “framework” for forming capacitor 27, over contact pad 18. It is necessary to make a variety of measurements and judge whether or not the measured values are acceptable in the course of the formation of cylinder hole 27A. The measurement and judgment will be described later in detail, and a method for forming cylinder hole 27A will now be described.

FIGS. 2A to 11A show the periphery circuit section and the cell array end portion. FIGS. 2B to 11B show the cell array central portion. FIGS. 2C to 11C show an alignment mark section.

The plan views of FIGS. 2A and 2B, 4A and 4B, 6A and 6B, 8A and 8B, and 10A and 10B show components formed in the respective manufacturing steps shown in the figures. Components formed on the surface of the device are drawn by solid lines, and primary components under the surface of the device are drawn by broken lines assuming that films between the surface of the device and the underlying primary components are not light-transmissive. The plan views of FIG. 2C, 4C, 6C, 8C, and 10C also show components formed in the respective manufacturing steps shown in the figures. Components on the mark surface are drawn by solid lines, and components under the mark surface are diagrammatically shown for ease of illustration based on images obtained by capturing marks with a camera used at the time of measurement taking into consideration the transparency of the components themselves.

First, a description will be made of a manufacturing process from the step of forming STI 2 in silicon substrate 1 to the step of forming contact pads 18. FIGS. 2A to 2C are plan views showing the semiconductor device after the contact pad formation step, and FIGS. 3A to 3C are cross-sectional views taken along line AA shown in FIGS. 2A to 2C.

Active regions 3 are formed in silicon substrate 1 by forming STI 2, which forms a device isolation region. An oxide film is then formed as gate insulating film 4 on the surface of silicon substrate 1 in a thermal oxidation process, and a polysilicon film and a tungsten (W) film are formed on the oxide film in a CVD (chemical vapor deposition) process. A silicon nitride film (SiN) is further formed as insulating film 6 on the tungsten film in a CVD process.

Insulating film 6 is then patterned into a predetermined shape, and the polysilicon film and the tungsten film are etched by using patterned insulating film 6 as a mask to form gate electrodes 5. A silicon nitride film is so formed in a CVD process that it covers stacked structures formed of gate electrodes 5 and insulating films 6, and the silicon nitride film is anisotropically etched to form sidewall insulating films 7, each of which covers the side surfaces of corresponding gate electrode 5 and insulating film 6. A conductive impurity is introduced in an ion implantation process into part of silicon substrate 1 between gate electrodes 5, specifically, the vicinity of the surface of silicon substrate 1 that is not covered with sidewall insulating films 7. The conductive impurity is then thermally diffused so that diffusion layers 8 are formed. The MOS transistors are thus formed.

Each of the stacked structures formed of gate electrode 5 and insulating film 6 has a convex shape with respect to the surface of silicon substrate 1, as shown in FIGS. 3A and 3B. To planarize the convexly stepped surface, an insulating material is applied to fill the gap between the stacked structures and form first interlayer insulating film 9, and the upper surface of first interlayer insulating film 9 is then planarized in a CMP (chemical mechanical polishing) process. First interlayer insulating film 9 is made of SOD (spin on dielectrics) and formed to a thickness of about 200 nm.

Further, in the cell array section, to form hole patterns having desired shapes in first interlayer insulating film 9 over desired diffusion layer 8, a photoresist film is applied onto first interlayer insulating film 9, and predetermined hole patterns are formed in the photoresist film by using a photolithography technique. First interlayer insulating film 9 is dry etched by using the photoresist film as a mask in which the hole patterns have been formed to form first holes (not shown) in first interlayer insulating film 9. After the photoresist film is removed, a conductive film made, for example, of tungsten is so formed that it fills the first holes. An excessive part of the conductive film formed on first interlayer insulating film 9 is so removed in a CMP process such that first contact plugs 10a and 10b formed of the conductive film are formed. The first contact plugs are thus connected to diffusion layer 8.

Second interlayer insulating film 11 formed of a silicon oxide film (SiO₂) is formed to a thickness of about 100 nm on first interlayer insulating film 9 in a CVD process. Second contact plug 12 is formed in second interlayer insulating film 11 in the cell array section, and fifth contact plugs 31 are formed in first interlayer insulating film 9 and second interlayer insulating fi'm 11 in the peripheral circuit section in a photolithography process, a dry etching process, a conducive film formation process, and a CMP process, as in the formation of first contact plugs 10 in first interlayer insulating film 9. As a result, second contact plug 12 is connected to first contact plug 10a, and fifth contact plugs 31 are connected to corresponding diffusion layer 8.

A tungsten film is formed to a thickness of about 50 nm on second interlayer insulating film 11 in a sputtering process, and a silicon nitride film is then formed to a thickness of about 250 nm on the tungsten film in a CVD process. The thus formed films are then so patterned in a photolithography process and a dry etching process that first wiring line 13 on which insulating film 14 is stacked is formed in the cell array section, and third wiring line 32 on which insulating film 33 is stacked is formed in the periphery circuit section. As a result, first wiring line 13 is connected to second contact plug 12, and third wiring line 32 is connected to fifth contact plugs 31. Subsequently, the side surface of first wiring line 13 is covered with sidewall insulating film 15 formed, for example, of a silicon nitride film, and the side surface of third wiring line 32 is covered with sidewall insulating film 34 at the same time. After third interlayer insulating film 16 made of SOD and having a film thickness of about 400 nm is so formed that it fills the gap between the wiring lines, and the upper surface of third interlayer insulating film 16 is planarized in a CMP process.

Subsequently, to form hole patterns in second interlayer insulating film 11 and third interlayer insulating film 16 in the cell array section, a photoresist film is applied onto third interlayer insulating film 16, and hole patterns are formed in the photoresist film by using a photolithography technique. Second interlayer insulating film 11 and third interlayer insulating film 16 are dry etched by using the photoresist film as a mask in which the hole patterns have been formed to form second holes (not shown) in second interlayer insulating film 11 and third interlayer insulating film 16.

After the photoresist film is removed, a conductive film made, for example, of tungsten is so formed that it fills the second holes. Subsequently, an excessive part of the conductive film formed on third interlayer insulating film 16 is so removed in a CMP process that third contact plugs 17 formed of the conductive film are formed. Third contact plugs 17 are thus connected to first contact plugs 10b. Further, a conductive film, such as a polysilicon film or a tungsten film in which a conductive impurity has been diffused, is formed to a thickness of about 50 nm on third interlayer insulating film 16. The conductive film is then patterned in a photolithography process and a dry etching process to form contact pads 18 in the cell array section. Diameter φ1 (see FIG. 2B) of each contact pad 18 in the plan view has a finished dimension set at 98±7 nm.

In an alignment mark section, an alignment mark having an appropriate shape is formed on the surface of the wafer whenever a photolithography step is carried out. In the exemplary embodiment, only alignment marks necessary to form cylinder holes 27A are shown. In the alignment mark section, first interlayer insulating film 9, second interlayer insulating film 11, and third interlayer insulating film 16 are sequentially formed on silicon substrate 1, as shown in FIG. 3C, and first alignment mark 18A is formed on third interlayer insulating film 16, as shown in FIGS. 2C and 3C. First alignment mark 18A in the plan view is a frame-shaped pattern having the following dimensions as shown in FIG. 2C: transverse dimension (dimension in X-axis direction) X1 of 20 μm, longitudinal dimension (dimension in Y-axis direction) Y1 of 20 μm, and a pattern width of 1 μm. First alignment mark 18A is made of the same material as that of contact pads 18.

First alignment mark 18A shown in FIG. 2C is a single pattern with its four sides connected with each other at vertices, but the pattern may be divided at the vertices (corners) and formed of four linear patterns corresponding to the four sides. First interlayer insulating film 9, second interlayer insulating film 11, and third interlayer insulating film 16 in the alignment mark section are formed simultaneously with the formation thereof in the cell array section and the periphery circuit section, and first alignment mark 18A is formed simultaneously with contact pads 18. As described above, the alignment mark section is processed simultaneously with processing of one or both of the cell array section and the periphery circuit section without any special processing performed only on the alignment mark section. In the following steps, the alignment mark section will therefore be described primarily on what differs from the cell array section and the periphery circuit section.

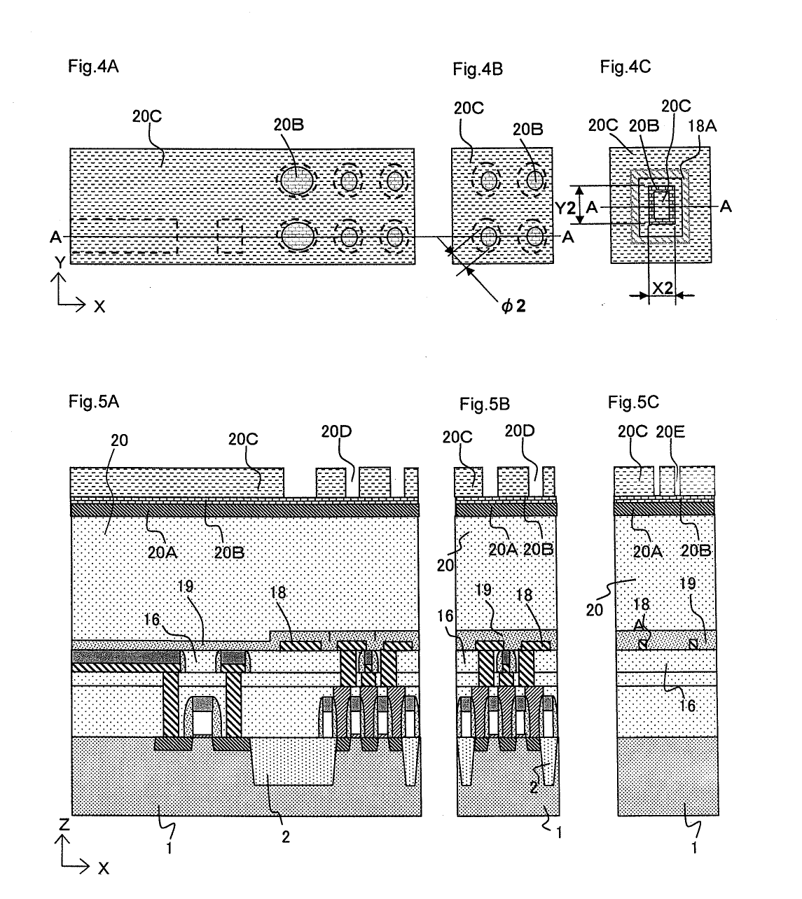

A description will next be made of a manufacturing process from the step of forming an insulating film on contact pads 18 to the step of forming a photoresist film for forming cylinder holes 27A. FIGS. 4A to 4C are plan views showing the semiconductor device after a photoresist film for forming the cylinder holes is formed, and FIGS. 5A to 5C are cross-sectional views taken along line AA shown in FIGS. 4A to 4C.

Cover film 19 formed of a silicon nitride film is formed on contact pads 18 and third interlayer insulating film 16 to a thickness of about 50 nm in a CVD process as a protective film in a wet etching process. Fourth interlayer insulating film 20 formed of a silicon oxide film is then formed on cover film 19 to a thickness ranging from about 500 to 1000 nm in a CVD process. Further, hard mask 20A formed of a carbon film and intermediate mask 20B formed of a silicon oxide film are sequentially formed on fourth interlayer insulating film 20 in a CVD process. After photoresist 20C is applied onto intermediate mask 20B, hole patterns 20D are formed in photoresist 20C by using a photolithography technique in positions corresponding to desired portions of contact pads 18. In this process, part of the upper surface of intermediate mask 20B is exposed at the bottom of each hole pattern 20D. Diameter φ2 (see FIG. 4B) of each hole pattern 20D in the plan view has a finished dimension set at 64±2 nm.

In the alignment mark section, second alignment mark 20E is formed in photoresist 20C on intermediate mask 20B, as shown in FIG. 5C. In FIG. 4C, second alignment mark 20E in the plan view corresponds to the exposed portion of the upper surface of intermediate mask 20B. Second alignment mark 20E in the plan view is a frame-shaped square pattern having the following dimensions: transverse dimension X2 of 10 μm, longitudinal dimension Y2 of 10 μm, and a pattern width of 0.3 μm.

The layout of the alignment marks in the “plan view,” in which they are viewed in the direction perpendicular to the XY plane coordinates, is designed as follows: Second alignment mark 20E is so located in first alignment mark 18A that the centers thereof coincide with each other and the gap between the two marks in the “XY direction,” which is the direction toward arbitrary coordinates with respect to an origin in the XY plane, is 5 μm.

Second alignment mark 20E (portion labeled with reference character 20B in FIG. 4C) is a single pattern with its four sides connected with each other at vertices, but the pattern may be divided at the corners and formed of four linear patterns corresponding to the four sides. Further, in the following description, photoresist 20C in which hole patterns 20D have been formed is called resist mask 20D, and photoresist 20C in which second alignment mark 20E has been formed is called resist mask 20E in some cases for ease of description.

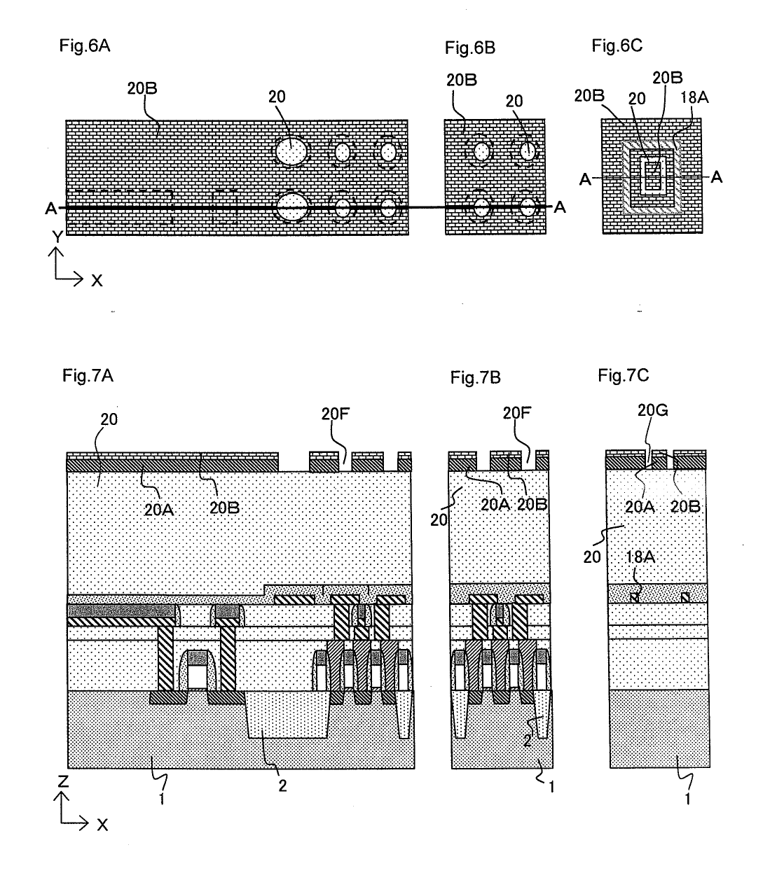

A description will next be made of the step of transferring the hole patterns in photoresist 20C to hard mask 20A and intermediate mask 20B. FIGS. 6A to 6C are plan views showing the semiconductor device after the hole patterns for forming the cylinder holes are transferred to the hard mask and the intermediate mask, and FIGS. 7A to 7C are cross-sectional views taken along line AA shown in FIGS. 6A to 6C.

Intermediate mask 20B exposed at the bottom of each hole pattern 20D is dry etched by using photoresist 20C as an etching mask to form a hole pattern (not shown) in intermediate mask 20B. Hard mask 20A exposed at the bottom of each hole pattern (not shown) is then dry etched by using intermediate mask 20B as an etching mask to form hole pattern 20F in intermediate mask 20B and hard mask 20k In this process, photoresist 20C formed on intermediate mask 20B is removed along with the portions of intermediate mask 20B and hard mask 20A that correspond to the positions of hole patterns 20D in the dry etching process. As a result, part of the upper surface of fourth interlayer insulating film 20 is exposed at the bottom of each hole patterns 20F, as shown in FIGS. 6A and 6B.

In the alignment mark section, groove pattern 20G having the same square shape as that of second alignment mark 20E in the plan view is formed in intermediate mask 20B and hard mask 20A. Part of the upper surface of fourth interlayer insulating film 20 is exposed at the bottom of groove pattern 20G, as shown in FIG. 7C. Groove pattern 20G corresponds to the exposed portion of the upper surface of fourth interlayer insulating film 20 and is therefore labeled with reference character 20 in FIG. 6C.

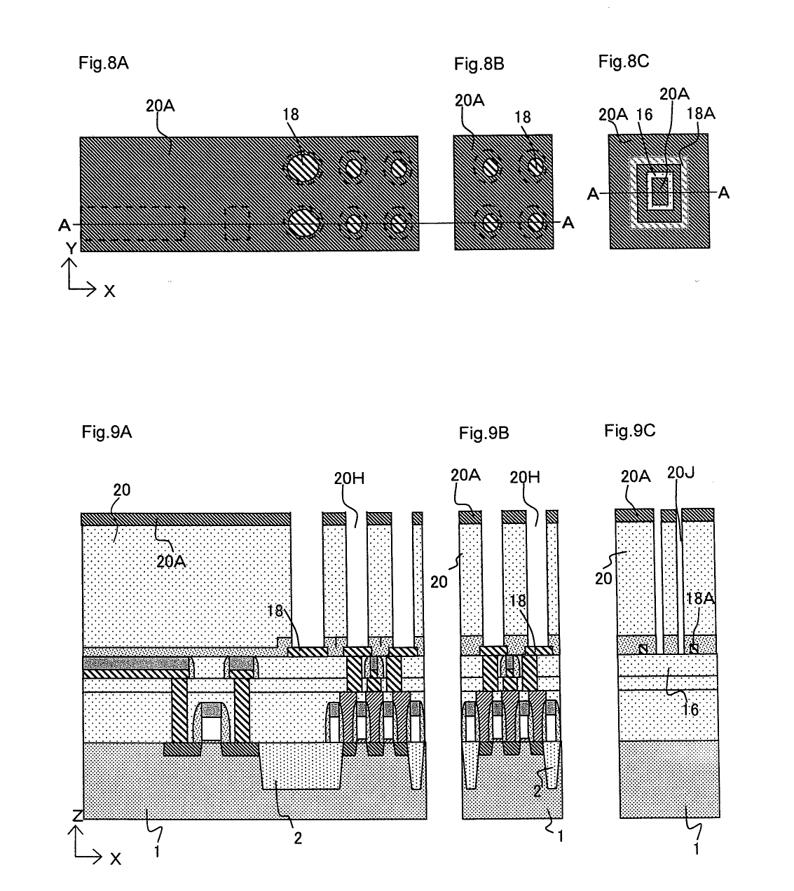

A description will next be made of the step of transferring hole patterns 20F in hard mask 20A to fourth interlayer insulating film 20. FIGS. 8A to 8C are plan views showing the semiconductor device after the hole patterns in the hard mask are transferred to the fourth interlayer insulating film, and FIGS. 9A to 9C are cross-sectional views taken along line AA shown in FIGS. 8A to 8C.

The portion of fourth interlayer insulating film 20 that is exposed at the bottom of each hole pattern 20F shown in FIGS. 7A and 7B is dry etched by using intermediate mask 20B and hard mask 20A as an etching mask to form hole pattern 20H in fourth interlayer insulating film 20. Intermediate mask 20B is removed in the dry etching process. Part of the upper surface of each contact pad 18 is exposed at the bottom of corresponding hole pattern 20H. In FIGS. 8A and 8B, hole patterns 20H correspond to the exposed portions of the upper surfaces of contact pads 18 and are labeled with reference character 18.

In the alignment mark section, groove pattern 20J having the same square shape as that of second alignment mark 20E in the plan view is formed in fourth interlayer insulating film 20. Part of the upper surface of third interlayer insulating film 16 is exposed at the bottom of groove pattern 20J, as shown in FIG. 9C. Groove pattern 20J corresponds to the exposed portion of the upper surface of third interlayer insulating film 16 and is therefore labeled with reference character 16 in FIG. 8C.

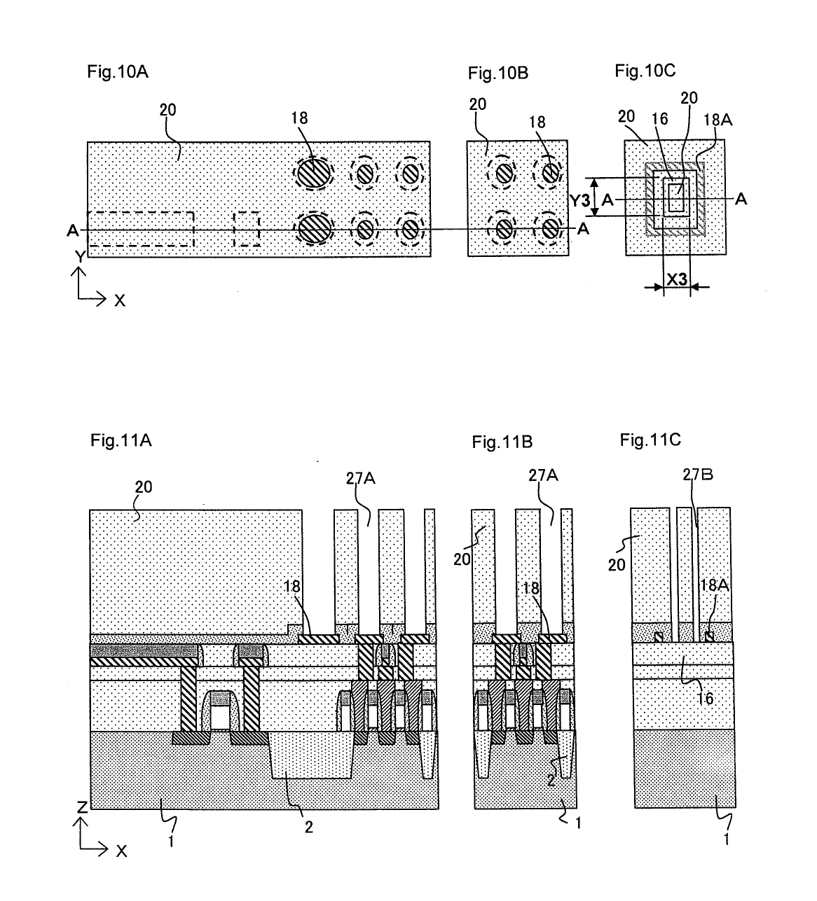

A description will next be made of the step of forming cylinder holes 27A. FIGS. 10A to 10C are plan views showing the semiconductor device after the cylinder holes are formed, and FIGS. 11A to 11C are cross-sectional views taken along line AA shown in FIGS. 10A to 10C.

Hard mask 20A left on fourth interlayer insulating film 20 is removed in an ashing process so that cylinder holes 27A are formed as shown in FIGS. 11A and 11B. Part of the upper surface of each contact pad 18 is exposed at the bottom of corresponding cylinder hole 27A. The pattern of each cylinder hole 27A is therefore labeled with reference character 18 in FIGS. 10A and 10B.

In the alignment mark section, square groove pattern 27B having transverse dimension X3 and longitudinal dimension Y3 is formed in fourth interlayer insulating film 20. Part of the upper surface of third interlayer insulating film 16 within first alignment mark 18A is exposed at the bottom of groove pattern 27B, as shown in FIG. 11C. Groove pattern 27B corresponds to the exposed portion of the upper surface of third interlayer insulating film 16 and is therefore labeled with reference character 16 in FIG. 10C. It is noted that transverse dimension X3, longitudinal dimension Y3, and the width dimension of groove pattern 27B may slightly differ from measured values of second alignment mark 20E due to a side etching phenomenon in which the dry etching proceeds in an unintended direction in the XY plane.

A description will next be made of the semiconductor device manufacturing method according to the exemplary embodiment with reference to two of the steps in the manufacturing method described above, the step of forming contact pads 18 and the step of forming cylinder holes 27A. The step of forming contact pads 18 is called a first step, and the step of forming cylinder holes 27A is called a second step.

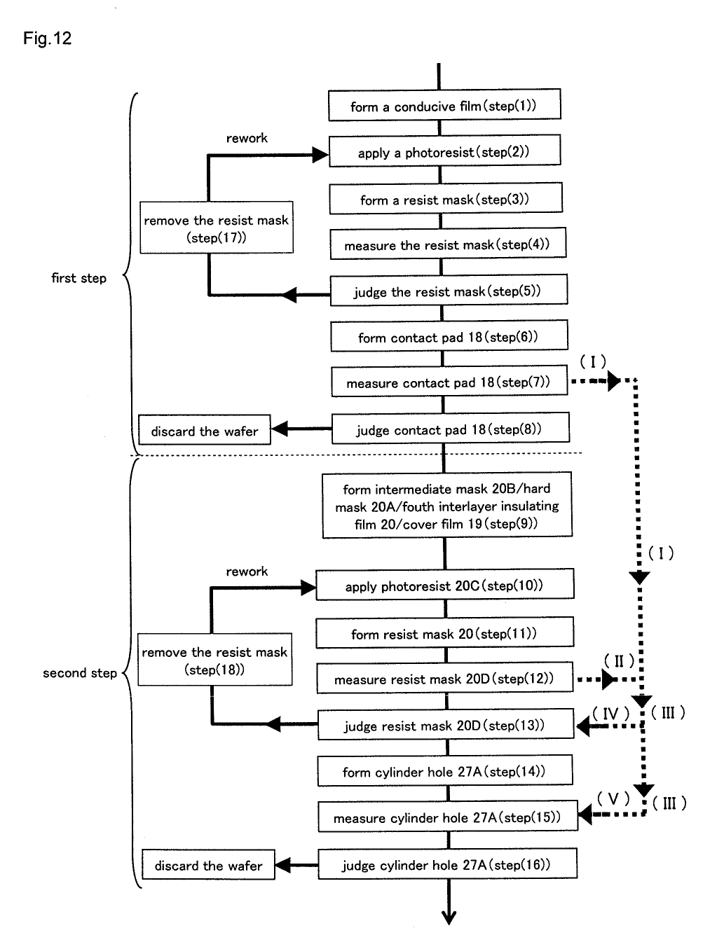

FIG. 12 is a manufacturing flowchart showing the two steps with reference to which the semiconductor device manufacturing method according to the exemplary embodiment is described in detail. The same components as those of the semiconductor device described with reference to FIGS. 2A, 3B, and 2C to 11A, 11B, and 11C have the same reference characters. A variety of steps in the first and second steps are numbered (1) to (18) so that they can be distinguished from each other.

In the first step, a conductive film that will form a first film to be processed is formed on third interlayer insulating film 16 (step (1)), followed by application and development of a photoresist (step (2)) and formation of a resist mask (step (3)). The dimension of each pattern in the resist mask and the position where an alignment mark is formed are then measured (step (4)), and whether or not the resist mask is defective is judged (step (5)).

A wafer having been judged to be defective in step (5) is temporarily rejected from the manufacturing process, and the resist mask is removed (step (17)). The resultant wafer is returned to the manufacturing process, which is resumed from the application of a photoresist (step (2)). On the other hand, a wafer having been judged to be non-defective in step (5) undergoes a step of forming contact pads 18 corresponding to a first pattern in the first film to be processed (step (6)). Subsequently, the dimension of the pattern in each contact pad 18 that corresponds to a first distance is measured (step (7) corresponding to first measurement step), and whether or not contact pad 18 is defective is judged (step (8)). A wafer having been judged to be defective at this point is discarded because it is difficult to rework the wafer any more.

In the second step, cover film 19 and fourth interlayer insulating film 20, which will form a second film to be processed, hard mask 20A, and intermediate mask 20B are sequentially formed over contact pads 18 (step (9)), followed by application and development of photoresist 20C over the second film to be processed via hard mask 20A and intermediate mask 20B (step (10)) and formation of resist mask 20D corresponding to a second pattern (step (11)). The dimension of each pattern corresponding to a second distance in resist mask 20D and the position where second alignment mark 20E is formed are measured (step (12) corresponding to second measurement step), and whether or not resist mask 20D is defective is judged (step (13)).

A wafer having been judged to be defective in step (13) is temporarily rejected from the manufacturing process, and the resist mask is removed (step (18)). The resultant wafer is returned to the manufacturing process, which is then resumed from the application of photoresist 20C (step (10)). On the other hand, a wafer having been judged to be non-defective in step (13) undergoes a step of forming cylinder holes 27A corresponding to a third pattern in the second film to be processed by using resist mask 20D (step (14)). Subsequently, the dimension of the pattern in each cylinder hole 27A that corresponds to a third distance is measured (step (15)) corresponding to third measurement step), and whether or not cylinder hole 27A is defective is judged (step (16)). A wafer having been judged to be defective at this point is discarded because it is difficult to rework the wafer any more.

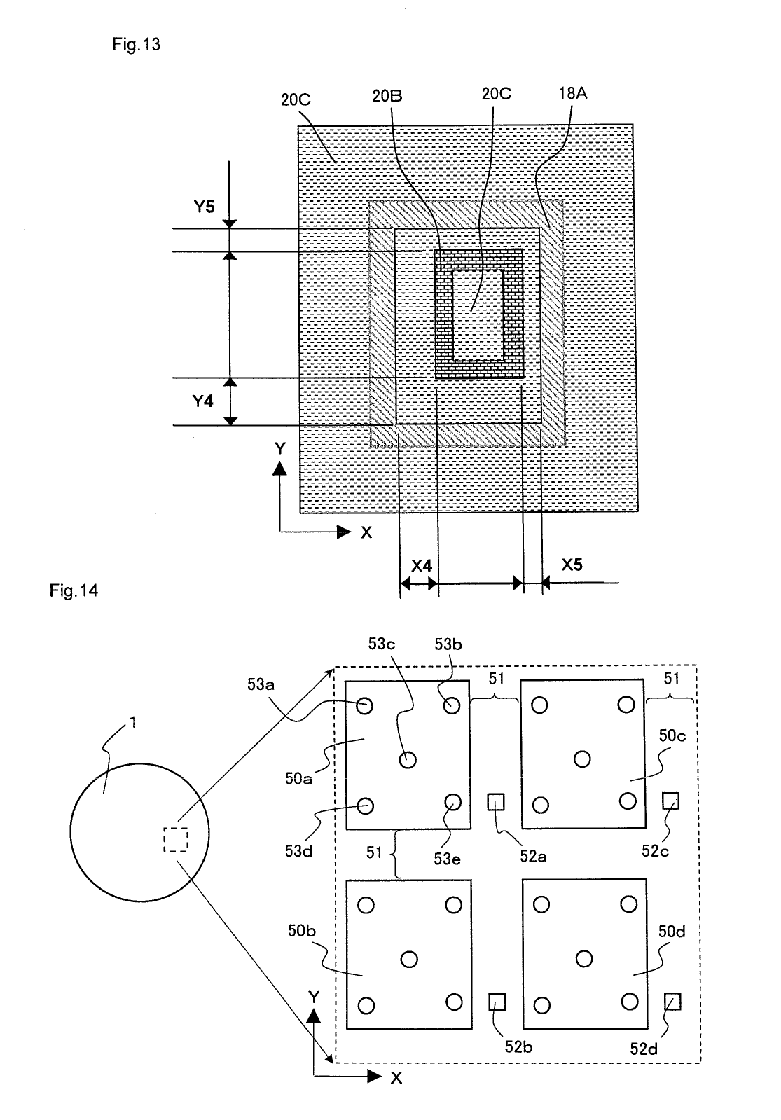

A description will next be made of a method for measuring the position where second alignment mark 20E is formed in step (12). FIG. 13 shows an exemplary image obtained by capturing the alignment mark section with a camera at the time of measurement in step (12) shown in FIG. 12. FIG. 13 corresponds to an image obtained by capturing the alignment mark section shown in FIG. 4C.

In the alignment mark section, cover film 19, fourth interlayer insulating film 20, hard mask 20A, intermediate mask 20B, and photoresist 20C are stacked on first alignment mark 18A, as shown in FIG. 5C, which is the cross-sectional view taken along line AA in FIG. 4C. Since each of cover film 19, fourth interlayer insulating film 20, hard mask 20A, intermediate mask 20B, and photoresist 20C is light-transmissive, the upper surface of intermediate mask 20B exposed at the bottom of resist mask 20E shown in FIG. 5C and first alignment mark 18A can be visually recognized in the image shown in FIG. 13.

It is therefore possible to detect the position of the edge of each of first alignment mark 18A and second alignment mark 20E (labeled with reference character 20B) by performing image processing on the image shown in FIG. 13, specifically the region containing the two alignment marks, or illuminating the region with laser light in the X and Y directions. Further, the amounts of shift X4 and X5 between the two alignment marks in the X direction and the amounts of shift Y4 and Y5 between the two alignment marks in the Y direction can be calculated from the difference in the positions of the edges between the two alignment marks in the X-axis direction and the difference in the positions of the edges between the two alignment marks in the Y-axis direction. A method for detecting an edge of a pattern will be described later.

When the amounts of shift X4 and X5 in the X-axis direction are equal to each other, it is judged that first alignment mark 18A and second alignment mark 20E are aligned with each other in the X-axis direction. In theimage shown in FIG. 13, however, X4>X5 indicates that second alignment mark 20E is shifted with respect to first alignment mark 18A toward the positive (+) side in the X-axis direction. Although not described in detail, the relationship between the two alignment marks in terms of the amounts of shift Y4 and Y5 in the Y-axis direction is equal to the relationship in terms of the amounts of shift in the X-axis direction, and the image shown in FIG. 13 shows that second alignment mark 20E is shifted with respect to first alignment mark 18A toward the positive (+) side in the Y-axis direction.

A description will next be made of the layout of semiconductor devices and alignment marks on a wafer. FIG. 14 is a plan view showing an example of the layout of semiconductor devices and alignment marks on a wafer. In FIG. 14, the region surrounded by the broken line on the surface of silicon substrate 1 is enlarged and shown to the right of silicon substrate 1.

Semiconductor devices are arranged along the X-axis and Y-axis directions on the surface of the wafer. Scribe region 51 is provided between adjacent semiconductor device regions in the X-axis and Y-axis directions on the wafer, as shown in the broken-line box in FIG. 14. For example, scribe region 51 is provided between semiconductor device region 50a and semiconductor device region 50b, and scribe region 51 is provided between semiconductor device region 50a and semiconductor device region 50c.

Since semiconductor device regions 50a to 50d are configured in the same manner, they may be labeled with the same reference character 50. However, to make a description with these regions distinguished from each other, lowercase alphabetical characters “a” to “d” are added to reference character 50. When a description common to semiconductor device regions 50a to 50d is made and hence it is not necessary to distinguish them from each other, reference character 50 is used collectively. The same holds true for reference characters 52a to 52d representing alignment mark sections and reference characters 53a to 53e representing the locations where the dimension of patterns in resist mask 20D are measured.

When step (12) shown in FIG. 12 is carried out, resist mask 20D is formed on each semiconductor device region 50 shown in FIG. 14, and alignment mark 52 is so formed that the center line thereof substantially coincides with the center line of corresponding scribe region 51. In step (12), in which the position of second alignment mark 20E and the dimension of each pattern in resist mask 20D are simultaneously measured, it is desirable in the exemplary embodiment to measure the pattern in resist mask 20D that is closest to second alignment mark 20E. This measurement procedure will be described below with reference to a specific example. When second alignment mark 20E in alignment mark section 52a is paired with resist mask 20D in semiconductor device region 50a for measurement, the dimension of a pattern in resist mask 20D should not be measured at the location indicated by reference character 53a, 53b, or 53c but is preferably measured at the location indicated by reference character 53e.

The reason for this will be described below. In the exemplary embodiment, the dimension of a pattern in resist mask 20D is used to determine the acceptable value in overlaying second alignment mark 20E (hereinafter referred to as acceptable overlay value). The acceptable overlay value will be described later in detail. In a photolithography step, the dimension of a resist pattern changes with the in-plane position on a wafer. Reducing the distance between objects to be measured, second alignment mark 20E and a pattern in resist mask 20D, minimizes the shift in correlation between measured second alignment mark 20E and a measured pattern in resist mask 20D resulting from the wafer in-plane variation that occurs in a photolithography step.

The approach of reducing the distance between the location where the dimension of a pattern in resist mask 20D is measured and the alignment mark section also holds true for the combinations of alignment mark sections 52b to 52d and semiconductor device regions 50b to 50d.

Referring to the step flowchart shown in FIG. 12, the semiconductor device manufacturing method according to the exemplary embodiment includes step (1) of forming the first film to be processed, step (6) of forming the first pattern, step (7) as the first measurement step, step (9) of forming the second film to be processed, step (11) of forming the second pattern, and step (12) as the second measurement step. The second pattern is judged in step (13) based on either the first distance or a value calculated from the first and second distances.

Judging whether or not the second pattern is defective based on the first distance in the actually formed first pattern or a value calculated from the first and second distances allows the acceptable value for the second pattern to be greater than an acceptable design value determined in a blanket manner. Measuring an actually formed pattern and increasing the acceptable value range based on which whether or not a product is judged to be defective allows a product that is actually not defective but judged to be defective to be rescued, whereby the rework rate and the defect rate can be lowered.

In the exemplary embodiment, the semiconductor device manufacturing method further includes step (14) of forming the third pattern and step (15) as the third measurement step, and a measurement region in the third measurement step is determined based on either the first distance or the calculated value described above.

In FIG. 12, the procedure of using the result from the first measurement step and the result from the second measurement step to judge the second pattern and carry out the third measurement step is labeled with Roman numerals (I) to (V).

A description will next be made of an acceptable design value and an acceptable overlay value for contact pads 18 corresponding to the first pattern, hole patterns 20D corresponding to the second pattern, and cylinder holes 27A corresponding to the third pattern.

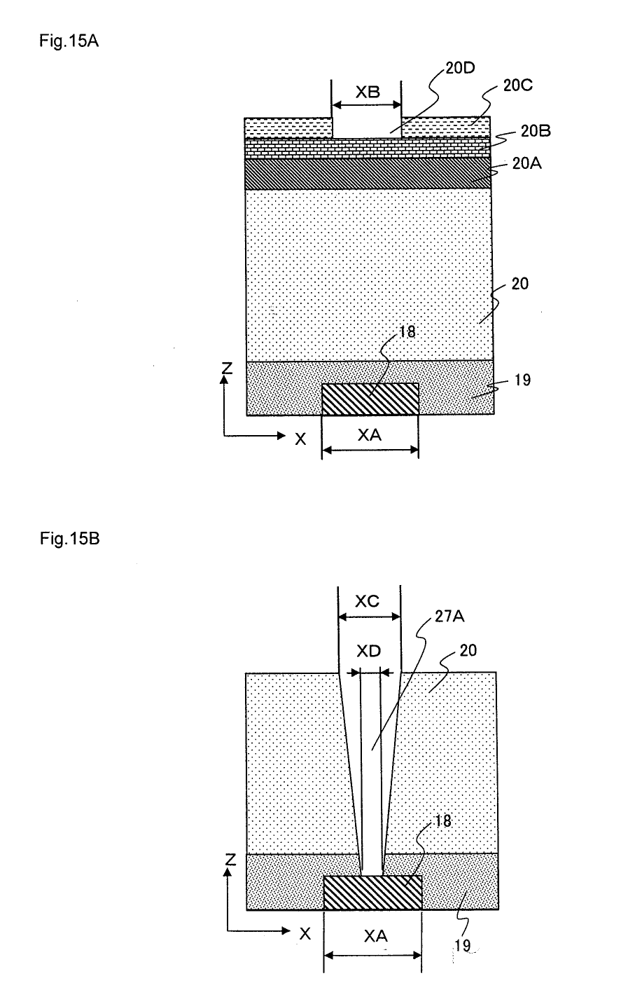

FIG. 15A is a cross-sectional view showing part of the semiconductor device after hole pattern 20D is formed. FIG. 15B is a cross-sectional view showing part of the semiconductor device after cylinder holes 27A are formed.

As shown in FIG. 15A, let XA be the diameter of contact pad 18 formed under cover film 19, and XB be the diameter of the opening of hole pattern 20D formed above contact pad 18 via cover film 19, fourth interlayer insulating film 20, hard mask 20A, and intermediate mask 20B. As described with reference to FIG. 2B, diameter XA of contact pad 18 is set at 98 nm as a design value, and the acceptable design value is set at XA=98±7 nm. Further, as described with reference to FIG. 4B, diameter XB of the opening of hole pattern 20D is set at 64 nm as a design value, and the acceptable design value is set at XB=64±2 nm. Design diameter XA of contact pad 18 is greater than design diameter XB of the opening of hole pattern 20D.

Cylinder hole 27A shown in FIG. 15B has a structure in which the sidewall is inclined and the diameter of the upper opening is greater than that of the lower opening. Diameter XC of the upper opening of cylinder hole 27A shown in FIG. 15B is equal to diameter XB of the opening of hole pattern 20D. However, since the sidewall of cylinder hole 27A is inclined, opening diameter XD at the bottom of cylinder hole 27A is smaller than opening diameter XC, and the acceptable design value is set at XD=55±2 nm.

Opening diameter XD can be calculated as a value correlating with opening diameter XC based on the thickness of fourth interlayer insulating film 20, in which cylinder hole 27A is formed, and etching conditions including the etching rate at which cylinder hole 27A is processed. That is, opening diameter XD can be expressed by using the thickness of fourth interlayer insulating film 20 and coefficient k1 determined by the etching conditions as follows: opening diameter XD=opening diameter XC×k1. Since opening diameter XC≈opening diameter XB, opening diameter XD=opening diameter XB×k1. Further, when opening diameter XC≠opening diameter XB due to an etching conversion difference, conversion coefficient k2 can be used to derive the following equation: opening diameter XC=opening diameter XB×k2. In this case, the following equation can be derived: opening diameter XD=opening diameter XB×k1×k2.

From the viewpoint of designing, the bottom of cylinder hole 27A must be present above the upper surface of contact pad 18. The acceptable overlay value XE for the first alignment mark and the second alignment mark, which corresponds to the overlay between the bottom of cylinder hole 27A and contact pad 18, is therefore calculated by XE=(XA−XD)/2. The equation shows that acceptable overlay value XE depends on diameter XA and opening diameter XD.

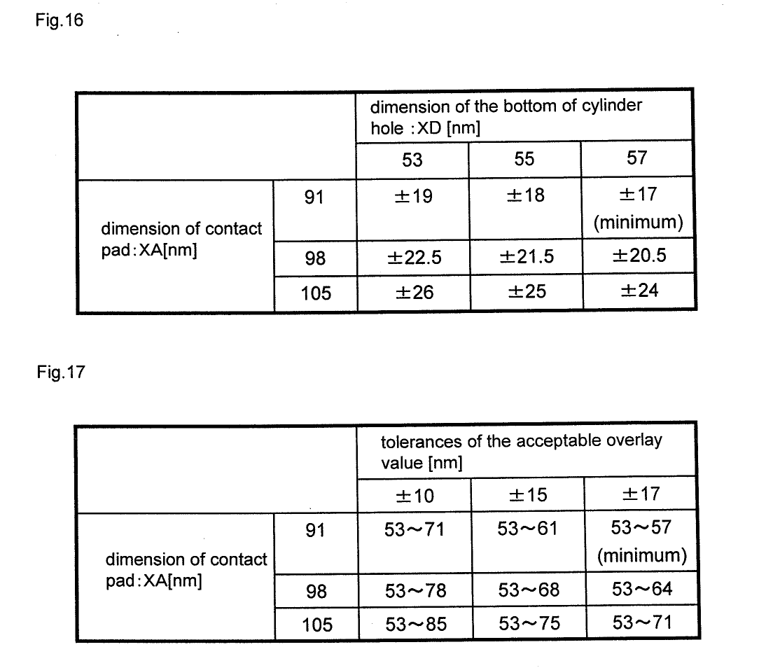

FIG. 16 is a table summarizing possible tolerances of acceptable overlay value XE within the acceptable design value ranges of diameter XA and opening diameter XD. The table shown in FIG. 16 is referred to as Table 1 in the following description.

Possible tolerances of acceptable overlay value XE in Table 1 are obtained by substituting XA=98±7 nm and XD=55±2 nm, which are assumed in the exemplary embodiment, into the equation XE=(XA−XD)/2.

For example, when XD=55−2=53 nm and XA=98−7=91 nm, XE=(91−53)/2=19 or possible tolerance of acceptable overlay value XE is ±19 nm. In Table 1, when diameter XA of contact pad 18 is the minimum of 91 nm, and opening diameter XD at the bottom of cylinder hole 27A is the maximum of 57 nm, acceptable overlay value XE (hereinafter referred to as acceptable design value XE1) has a tolerance of ±17 nm, which is the narrowest tolerance range.

In related art, irrespective of diameter XA of contact pad 18, acceptable design value XE1 is set to have a tolerance of ±17 nm and opening diameter XD is set to be 55±2 nm in all wafers of manufacturing lots in each of which histories in the manufacturing steps are recorded for a defined number of wafers, or in all wafers.

In contrast, in the exemplary embodiment, acceptable overlay value XE2 is calculated from measured diameter XA and measured opening diameter XD (XE2 is hereinafter also referred to as calculated value), as shown in Table 1. According to the method, acceptable overlay value XE2 can be greater than acceptable design value XE1.

FIG. 17 is a table summarizing possible acceptable values XD1 of opening diameter XD for the tolerances of the acceptable overlay value within the acceptable design value range of diameter XA. The table shown in FIG. 17 is referred to as Table 2 in the following description.

Minimum opening diameters XD for all the cases are set at the same value (53 nm) that does not degrade contact resistance with contact pad 18, as shown in Table 2.

As shown in Table 2, when the tolerance of the acceptable overlay value is the maximum of ±17 nm, and measured diameter XA of contact pad 18 is the minimum of 91 nm, acceptable value XD1 of cylinder hole 27A is 55±2 nm, which has the narrowest range, that is, from 53 nm to 57 nm. Below the field where acceptable value XD1 ranges from “53 to 57 nm” is shown acceptable value XD1 when measured diameter XA of contact pad 18 is 98 nm. In this case, since there is an additional margin of 98-91=7 nm, the upper limit of opening diameter XD is 57+7=64 nm, which is greater than the upper limit of 55 nm in related art, resulting in an increase in the range of acceptable value of opening diameter XD. This means that the range of the acceptable overlay value effectively increases.

Table 2 also shows acceptable values XD1 of cylinder hole 27A when the tolerance of the acceptable overlay value is “±15 nm” and “±10 nm.” When the tolerance of the acceptable overlay value is changed from “±17 nm” to “±15 nm,” the upper limit of acceptable value XD1 increases by 4 nm (=(17−15)×2) as compared with the case where the tolerance of the acceptable overlay value is ±17 nm. When the tolerance of the acceptable overlay value is changed from “±17 nm” to “±10 nm,” the upper limit of acceptable value XD1 increases by 14 nm (=(17−10)×2) as compared with the case where the tolerance of the acceptable overlay value is ±17 nm.

In the exemplary embodiment, an actual acceptable value can be greater than an acceptable design value by recalculating the tolerance of opening diameter XD of cylinder hole 27A in accordance with the tolerance of the acceptable value of diameter XA of contact pad 18 or the tolerance of the acceptable overlay value for the diameter XA of the contact pad and opening diameter XD of cylinder hole 27A.

Further, opening diameter XD can be calculated as a value correlating with opening diameter XC based on the thickness of fourth interlayer insulating film 20 and the dry etching conditions, and opening diameter XC is equal to opening diameter XB, as described above. It is therefore possible to replace Tables 1 and 2 with tables in which opening diameter XD is converted into opening diameters XB. In this case, the acceptable value of opening diameter XB can be greater than an acceptable design value by recalculating the tolerance of opening diameter XB of the hole pattern in accordance with the tolerance of the acceptable value of diameter XA of contact pad 18 or the tolerance of the acceptable overlay value for diameter XA of the contact pad and opening diameter XB of the hole pattern. As a result, acceptable overlay value XE2 for the first and second alignment marks can be increased.

It is noted that the thickness of each interlayer insulating film, the amount of etching, and other process conditions under which actual processes are carried out vary whenever a wafer or a manufacturing lot is changed. Acceptable overlay value XE2 is therefore preferably set whenever a wafer or a manufacturing lot is changed.

A description will next be made of a method for determining the location where cylinder hole 27A, which corresponds to the third pattern, is measured and a method for measuring the dimension of the pattern. In the exemplary embodiment, a measuring apparatus automatically determines cylinder hole 27A where the measurement is performed and measures cylinder hole 27A.

The automatic measurement means that an operator does not determine the location where the dimension of a pattern is measured or measure the dimension of the pattern but an information processing apparatus does. The automatic measurement allows the operator only to place a wafer in a cassette in the measuring apparatus and remove the cassette from the measuring apparatus when a wafer has a large number of measurement locations or when a plurality of wafers are measured for each manufacturing lot.

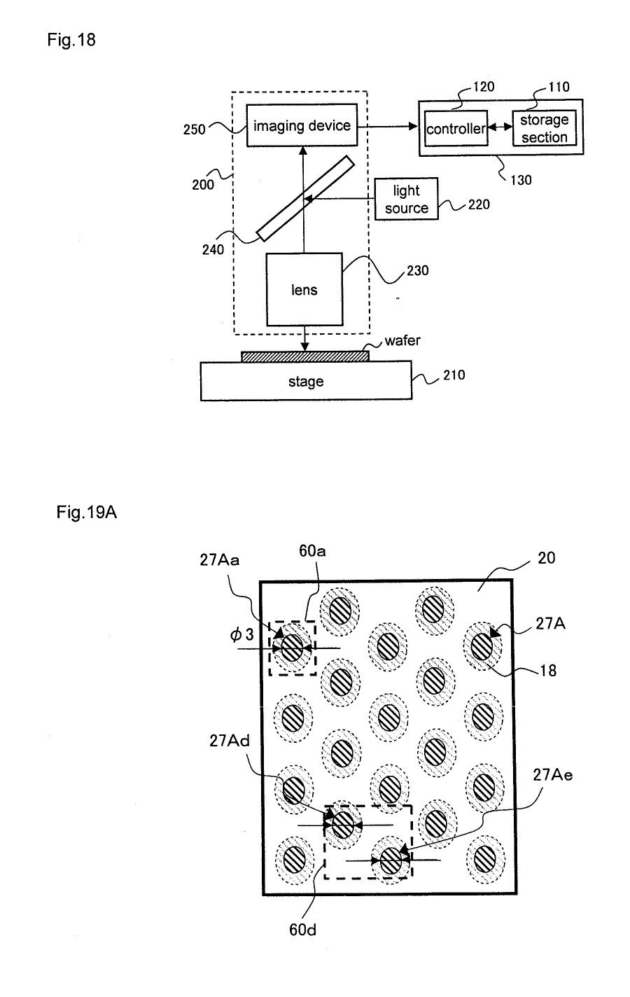

A brief description will be made of an example of the configuration of the measuring apparatus that performs the automatic measurement. FIG. 18 is a block diagram showing an example of the configuration of a measuring apparatus used in the exemplary embodiment.

The measuring apparatus includes stage 210 on which a wafer is placed, light source 220 that illuminates the wafer with light, camera 200 that captures an image of an alignment mark, and personal computer (hereinafter referred to as PC) 130 that analyzes the image outputted from camera 200, as shown in FIG. 18.

Camera 200 includes lens 230 that enlarges an image of the alignment mark, beam splitter 240 that separates the light with which the surface of the wafer is illuminated and light reflected off the surface of the wafer from each other, and imaging device 250 that converts the image of the alignment mark enlarged through lens 230 into an electric signal. Beam splitter 240 allows the light emitted from light source 220 to enter lens 230 and allows the light reflected off the surface of the wafer and passing through lens 230 to enter imaging device 250. Imaging device 250 is connected to PC 130 in a communicable manner. Imaging device 250 is, for example, a CCD (charge coupled device) image sensor or a CMOS (complementary metal oxide semiconductor) image sensor.

An A/D converter circuit (not shown) may be provided between imaging device 250 and PC 130 and may convert image data outputted from imaging device 250 in the form of analog signal into digital signal. Further, a wafer transfer apparatus (not shown) is used in the step of testing a semiconductor device. The wafer transfer apparatus unloads a wafer from a cassette and mount the wafer on stage 210, moves stage 210 so that a measurement location comes under lens 230, and picks up the wafer having undergone pattern dimension measurement from stage 210 and reloads the wafer into the cassette. These operations will not be described in detail.

PC 130 includes storage section 110 and controller 120. Controller 120 includes a CPU (central processing unit) (not shown) that executes processes in accordance with an automatic measurement program and a memory (not shown) that stores the automatic measurement program. Storage section 110 registers in advance an image used to identify measurement regions that surround the patterns of cylinder hole 27A and contact pad 18 to be measured. In the following description, the image is referred to as a registered image. The registered image shows, for example, a state in which the pattern of cylinder hole 27A is overlaid on the pattern of contact pad 18.

A brief description will be made of processes executed by controller 120 in accordance with the automatic measurement program. Controller 120 executes a region identification process for identifying a measurement region and a measurement process for measuring the diameter of a cylinder hole in accordance with the automatic measurement program.

The region identification process includes referring to the registered image stored in storage section 110, detecting a location where the image outputted from camera 200 substantially coincides with the registered image, and assigning the detected location as a measurement region. The measurement process includes setting a cursor in the measurement region, performing image processing to detect edges of the pattern of the cylinder hole in the cursor, and measuring the distance between the edges. The distance is calculated taking into consideration the magnification of lens 230.

The cursor forms a measurement region and determines a measurement range. The cursor in the exemplary embodiment has a rectangular shape, and the longitudinal and transverse dimensions of the cursor (hereinafter the dimensions are collectively referred to as “cursor dimensions”) are set in advance in accordance with diameter XA of contact pad 18 or opening diameter XB of hole pattern 20D. A registered image typically contains a plurality of cylinder holes 27A, and controller 120 sets the cursor in such a way that one cylinder hole 27A is within the cursor. An image-processing-based method for detecting an edge of a pattern will not be described in detail because an example thereof is disclosed in Patent Document 1.

In the region identification process, in which controller 120 refers to the registered image and identifies a measurement region in the image, controller 120 judges whether or not any location substantially coincides with the registered image. When the judgment result shows that there is a location that coincides with the registered image, controller 120 assigns the location as a measurement region and proceeds to the following measurement process. On the other hand, when the judgment result shows that there is no location that coincides with the registered image, controller 120 issues a measurement error representing that no measurement can be performed. After issuing the measurement error, controller 120 cannot proceed to the following measurement process, and the measuring apparatus stops operating.

The method for detecting an edge of a pattern is not limited to the image-processing-based method described above but may alternatively be a method using a laser light source. A method using a laser light source includes providing in advance a laser light source (not shown) in the measuring apparatus as well as light source 220 shown in FIG. 18, identifying a measurement region, illuminating the region in the cursor with the laser light along the X-axis and Y-axis directions, and detecting an edge of a pattern based on the reflected light. In the following description, reference numeral 60 denotes the cursor, and an alphabetical lowercase character is added to reference character 60 when a plurality of cursors should be distinguished from each other in the description.

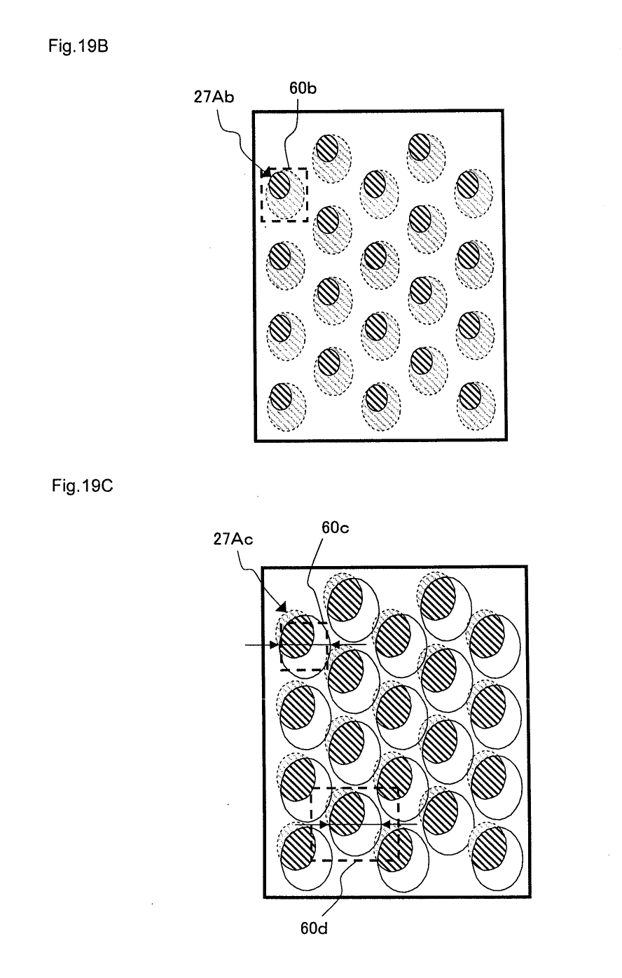

FIGS. 19A to 19C show images captured with camera 200, viewed from above, in which a plurality of cylinder holes 27A formed in fourth interlayer insulating film 20.

FIG. 19A shows an image representing a state in which the cylinder holes are formed in ideal positions above the contact pads. FIG. 19B shows an image representing a state in which the cylinder holes are not ideally overlaid above the contact pads but are shifted therefrom by a value greater than unacceptable design value. FIG. 19C shows an image representing a state in which the formed cylinder holes have a larger size than an acceptable design value. It is noted that cylinder holes 27A are present above contact pads 18, which are exposed at the bottom of cylinder holes 27A as described with reference to FIG. 15B.

A description will next be made of the procedure of automatic measurement performed by the measuring apparatus shown in FIG. 18 with reference to the image shown in FIG. 19A. It is assumed that the automatic measurement is performed on semiconductor device region 50a shown in FIG. 14 and that the wafer transfer apparatus (not shown) has moved stage 210 on which a wafer is placed in such a way that camera 200 can capture an image of location 53e where the dimension of a pattern in resist mask 20D is measured.

After camera 200 captures an image of cylinder hole 27A from above at location 53e where the dimension of a pattern in resist mask 20D has been measured, PC 130 checks whether or not there is a location where the image outputted from imaging device 250 substantially coincides with the registered image stored in storage section 110 and assigns the location that coincides with the registered image as a measurement region. PC 130 subsequently sets cursor 60a in the measurement region, performs image processing on single cylinder hole 27Aa to detect edges of cylinder hole 27Aa, and measures diameter φ3 shown in FIG. 19A.

A description will next be made of cases where automatic measurement is performed on the images shown in FIGS. 19A to 19C. It is assumed that an image of cursor 60a shown in FIG. 19A is stored in advance as a registered image in storage section 110.

Cylinder hole 27A is located within and overlaid on corresponding contact pad 18, and the center of cylinder hole 27A coincides with the center of contact pad 18, as shown in FIG. 19A. That is, cylinder hole 27A is positioned within a range of ±15 nm both in the X-axis and Y-axis directions with respect to contact pad 18. When the amount of shift is within the above range, the image in cursor 60a shown in FIG. 19A substantially coincides with the reference registered image, whereby PC 130 can detect edges of cylinder hole 27A being measured in cursor 60a and measure diameter φ3 of cylinder hole 27A.

On the other hand, in the image shown in FIG. 19B, each cylinder hole 27A is located within and overlaid on corresponding contact pad 18, but cylinder hole 27A is shifted from contact pad 18 by −15 nm or greater in the X-axis direction and +15 nm or greater in the Y-axis direction. As a result, part of the edge of cylinder hole 27A could overlap with the edge of contact pad 18, as shown in FIG. 19B.

In this case, in which cylinder hole 27A is shifted from the registered image by −15 nm or greater in the X-axis direction and by +15 nm or greater in the Y-axis direction, even when cursor 60b is set in the image shown in FIG. 19B, PC 130 does not recognize that the image in cursor 60b coincides with the registered image. PC 130 therefore judges that no location in the image shown in FIG. 19B coincides with the registered image and cannot detect cylinder hole 27Ab, which is the object to be measured. As a result, PC 130 issues a measurement error and stops performing the measurement processes. The phenomenon also occurs when the dimensions of cursor 60b are changed.

In the image shown in FIG. 19C, cylinder hole 27Ac is sized so that it extends off cursor 60c. In this case, PC 130 issues a measurement error, as in FIG. 19B. When cursor 60d, which is larger than cursor 60c is set, PC 130 conceivably judges whether or not cylinder hole 27Ac is defective for the automatic measurement.

When the cursor dimensions are set in advance to be those of cursor 60d, however, the following problem occurs. That is, when PC 130 measures cylinder hole 27A in the image shown in FIG. 19A, the cursor 60d shown in FIG. 19A contains two patterns, cylinder hole 27Ad and cylinder hole 27Ae. In this case, PC 130 cannot determine one of the objects to be measured, resulting in a measurement error.

As described above, when a set that comprises a predetermined registered image and cursor having predetermined dimensions is used as a reference, the measuring apparatus tends to issue a measurement error depending on the position where cylinder hole 27A is formed and the size thereof even when a product including cylinder hole 27A is not defective. When the measuring apparatus issues a measurement error and stops operating, the manufacturing is not performed smoothly, and the manufacture throughput becomes lowers.

In the exemplary embodiment, a plurality of types of registered images are stored in storage section 110 in advance taking into consideration variations in the position where hole pattern 20D, which serves as a mask for use in forming cylinder hole 27A, is formed. PC 130 measures the position of hole pattern 20D, selects one optimal image from among the plurality of types of registered images in accordance with a calculated value based on the measured value, and detects cylinder hole 27A to be measured, whereby automatic measurement can be performed without any measurement error.

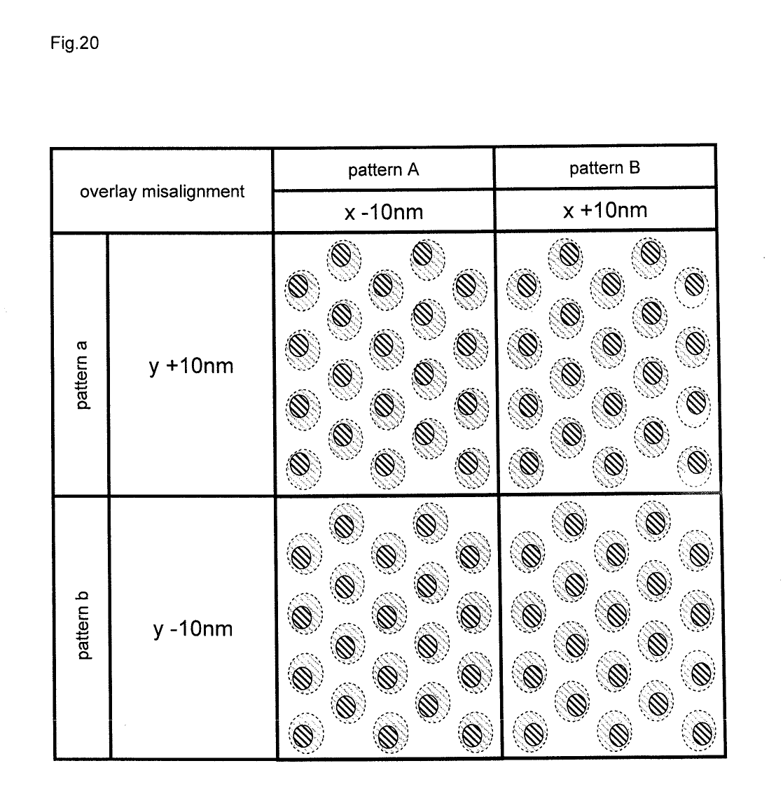

FIG. 20 is a table showing an example of the plurality of types of registered images. Since overlay misalignment needs to be taken into consideration in both the XY directions, it is necessary to provide registered images having overlay misalignment in the XY directions. FIG. 20 shows four registered images having overlay misalignment from an ideal state by ±10 nm in the XY directions.

In the table shown in FIG. 20, a shift in the transverse direction represents a shift in the X-axis direction, and a shift in the longitudinal direction represents a shift in the Y-axis direction. Hole pattern 20D shifted from the ideal state by −10 nm in the X-axis direction is labeled with reference character “A”, and hole pattern 20D shifted from the ideal state by +10 nm in the X-axis direction is labeled with reference character “B”. Similarly, hole pattern 20D shifted from the ideal state by +10 nm in the Y-axis direction is labeled with reference character “a”, and hole pattern 20D shifted from the ideal state by −10 nm in the Y-axis direction is labeled with reference character “b”. In the table shown in FIG. 20, for example, hole pattern 20D shifted from the ideal state by −10 nm in the X-axis direction and shifted from the ideal state by +10 nm in the Y-axis direction is called pattern Aa.

The four types of registered image shown in FIG. 20 are stored in storage section 110 in advance, and PC 130 compares a captured image, for example, the image shown in FIG. 19B, with the four types of registered image in terms of the position in the XY-plane coordinates where hole pattern 20D is formed and the position in the XY-plane coordinates where cylinder hole 27Ab is formed. Based on the comparison result, PC 130 selects a registered image similar to the image shown in FIG. 19B, specifically, the pattern-Aa image in which overlay misalignment between hole pattern 20D and cylinder hole 27Ab falls within the acceptable value range described with reference to Table 2, whereby automatic measurement can be performed without any measurement error.

Further, the cursor dimensions may be changed in accordance with the dimension of hole pattern 20D. As shown in FIG. 19C, setting cursor 60d having one side longer than the dimension of hole pattern 20D allows cylinder hole 27Ac to be surrounded by cursor 60d and PC 130 to perform the automatic measurement even on the image shown in FIG. 19C without any measurement error resulting from an insufficient cursor dimension region. In this case, the cursor dimensions may be changed in accordance with the dimension of contact pad 18 instead of that of hole pattern 20D.

The four registered images shown in FIG. 20 are presented by way of example, and the number of registered images is not limited to four. Further, the shape of the cursor is not limited to a rectangular shape but may be hexagonal or octagonal. Moreover, the exemplary embodiment, which has been described with reference to the case where cylinder hole 27A corresponding to the third pattern is automatically measured, may alternatively be applied to a case where hole pattern 20D corresponding to the second pattern is automatically measured. In this case, the cursor dimensions may be determined in accordance with the diameter of contact pad 18.

According to the semiconductor device manufacturing method in the exemplary embodiment, whether or not a hole pattern in a resist mask is defective is judged based on either the diameter of a contact pad or a value calculated from the diameter of the hole pattern and the diameter of the contact pad. Since whether or not the hole pattern is defective is judged based on overlay misalignment, such as a measured dimension of the contact pad or a value calculated from measured dimensions of the contact pad and the hole pattern, an acceptable value of the hole pattern can be set to be greater in accordance with an actually formed pattern than an acceptable design value determined in a blanket manner. As a result, the rework rate can be lowered to 1% or lower. Further, since a product that is not defective but has been judged to be defective in accordance with specifications determined in a blanket manner can be retrieved, the defect rate of the product can be lowered.

Further, in the exemplary embodiment, a measurement region is determined based on either the diameter of a contact pad or a value calculated from the diameter of a hole pattern in a resist mask and the diameter of the contact pad, and then a cylinder hole is measured. Since the measurement region is set in accordance with the diameter of an actually formed contact pad or the measurement region is set to cover an overlay misalignment acceptable value range determined based on the dimension of an actual pattern, a measuring apparatus can detect a cylinder hole to be measured even when the position where the cylinder hole is formed varies for each wafer or for each manufacturing lot. As a result, it is reduced that the measuring apparatus will issue a measurement error, whereby the product measurement throughput can be increased by at least 10%.

Moreover, since processes in each manufacturing step tend to vary for each wafer or for each manufacturing lot, using the calculated value described above, which is calculated based on a value measured for each wafer or each manufacturing lot, allows the acceptable value of a hole pattern or a cylinder hole to be increased in accordance with process conditions.

The exemplary embodiment has been described with reference to a hole pattern and a cylinder hole. The present invention is also applicable to a step in which it is necessary to control an overlay misalignment acceptable value between a pattern in a lower layer and a pattern in an upper layer, such as a case where two contact plugs are connected along the direction perpendicular to the surface of a semiconductor substrate and a case where a contact plug is formed above the upper surface of a wiring layer.

It is apparent that the present invention is not limited to the above embodiments, but may be modified and changed without departing from the scope and spirit of the invention.

What is claimed is:

1. A semiconductor device manufacturing method comprising:
forming a first film to be processed on a semiconductor substrate;
forming a first pattern in the first film to be processed;
measuring a first distance, which is a dimension in a predetermined direction in the first pattern;
forming a second film to be processed on the first pattern;
forming a second pattern in a photoresist formed on the second film to be processed; and
measuring a second distance, which is a dimension in a predetermined direction in the second pattern,
wherein whether or not the second pattern is defective is determined based on either the first distance or a value calculated from the first and second distances.

2. The semiconductor device manufacturing method according to claim 1,
wherein the calculated value is defined for each wafer or each manufacturing lot.

3. The semiconductor device manufacturing method according to claim 1, further comprising:
forming a third pattern in the second film to be processed by using the second pattern as an etching mask; and
measuring a third distance, which is a dimension in a predetermined direction in the third pattern,
wherein a measurement region for measuring the third distance is determined based on either the first distance or the calculated value.

4. The semiconductor device manufacturing method according to claim 3,
wherein the calculated value is obtained by halving the difference between the second distance multiplied by a coefficient and the first distance, and
the coefficient is determined based on a thickness of the second film to be processed and process conditions under which the third pattern is formed.

5. The semiconductor device manufacturing method according to claim 3, further comprising:
providing a plurality of images each of which contains the first pattern and the third pattern with the third pattern shifted from the center of the first pattern in a plane coordinate system to the extent that the third distance is measurable,
wherein the first and third patterns are compared with the plurality of images before the measurement region is determined, selecting an image containing first and third patterns that substantially coincide with the first and third patterns, and determining the selected image as a measurement region that surrounds the first and third patterns.

6. The semiconductor device manufacturing method according to claim 3,
wherein the measurement region has a plurality of sides each of which has a length corresponding to the first distance, and the plurality of sides surrounds the first and third patterns.
